(19) United States
(12) Patent Application Publication
(10) Pub. No.: US 2021/0013366 A1
(43) Pub. Date: Jan. 14, 2021

(54) GROUP 13 ELEMENT NITRIDE LAYER, FREE-STANDING SUBSTRATE, FUNCTIONAL ELEMENT, AND METHOD OF PRODUCING GROUP 13 ELEMENT NITRIDE LAYER

(71) Applicant: NGK INSULATORS, LTD., Nagoya-city (JP)

(72) Inventors: Masahiro SAKAI, NAGOYA-CITY (JP); Takashi YOSHINO, AMA-CITY (JP); Katsuhiro IMAI, NAGOYA-CITY (JP); Yoshitaka KURAOKA, OKAZAKI-CITY (JP)

(21) Appl. No.: 17/034,799

(22) Filed: Sep. 28, 2020

Related U.S. Application Data
(63) Continuation of application No. PCT/JP2019/005240, filed on Feb. 14, 2019.

(30) Foreign Application Priority Data
Mar. 29, 2018 (JP) 2018-064713

(51) Int. Cl. H01L 33/00; H01L 21/02; H01L 33/18; H01L 33/32; H01L 29/04; H01L 29/20; C30B 29/40; C30B 19/02; C30B 28/04; C23C 14/08; C23C 14/06; C23C 14/34; C23C 16/34

(52) U.S. Cl. CPC H01L 33/007; C23C 16/34; H01L 21/02488; H01L 21/0254; H01L 21/02595; H01L 21/02609; H01L 21/02642; H01L 21/02645; H01L 21/02625; H01L 33/18; H01L 33/32; H01L 29/045; H01L 29/2003; C30B 29/406; C30B 19/02; C30B 28/04; C23C 14/081; C23C 14/0617; C23C 14/34; H01L 21/0242

(57) ABSTRACT

A group 13 nitride layer is composed of a polycrystalline group 13 nitride and is constituted by a plurality of monocrystalline particles having a particular crystal orientation approximately in a normal direction. The group 13 nitride comprises gallium nitride, aluminum nitride, indium nitride or the mixed crystal thereof. The group 13 nitride layer includes an upper surface and a bottom surface, and a full width at half maximum of a (1000) plane reflection of X-ray rocking curve on the upper surface is 20000 seconds or less and 1500 seconds or more.

### CROSS-REFERENCE TO RELATED APPLICATIONS

This is a continuation of PCT/JP2019/005240, filed Feb. 14, 2019, which claims priority from Japanese Application No. 2018-064713, filed Mar. 29, 2018, the entire contents of which are hereby incorporated by reference.

### TECHNICAL FIELD

The present invention relates to a group 13 nitride layer, free-standing substrate, functional device and a method of producing a group 13 nitride layer.

### BACKGROUND ARTS

There have been known light emitting devices such as light emitting diodes (LEDs) that use sapphire (α-alumina single crystal) as a monocrystalline substrate, with various types of gallium nitride (GaN) layers formed thereon. For example, light emitting devices have been mass-produced having a structure in which an n-type GaN layer, a multiple quantum well (MQW) layer with an InGaN quantum well layer and a GaN barrier layer grown alternately therein, and a p-type GaN layer are formed in a grown manner in this order on a sapphire substrate.

Monocrystalline substrates are generally expensive, though having only a small area. In particular, while cost reduction in manufacturing LEDs using a large-area substrate has been demanded, it is not easy to mass-produce large-area monocrystalline substrates, and the manufacturing cost may further increase. Hence, inexpensive material has been required that can be substituted for gallium nitride or the like of such monocrystalline substrates. There have been proposed polycrystalline gallium nitride free-standing substrates that meet such a requirement (Patent documents 1 and 2).

### BACKGROUND ARTS

### Patent Documents

(Patent Document 1) Japanese Patent No. 5,770,905B
(Patent document 2) WO 2015/151902 A1

### SUMMARY OF THE INVENTION

According to the oriented gallium nitride layers as described in patent documents 1 and 2, as the cost can be considerably reduced compared with the case that a single crystal substrate is used, the industrial applicability is notable. However, there is a limit on the reduction of dislocation defects on the surface of the thus obtained gallium nitride film. Further, it was observed the reduction of yield of a functional layer which is considered to be caused by surface pits.

Further, in the case that a light-emitting device such as LED is provided on the gallium nitride layer, it is demanded to further improve the efficiency.

An object of the present invention is, in a group 13 nitride crystal layer including a plurality of monocrystalline particles having a particular crystal orientation in a normal direction, to reduce dislocation defects on the surface so that the yield and efficiency of a functional layer provided thereon can be further improved.

The present invention provides a group 13 nitride layer comprising a polycrystalline group 13 nitride,

the group 13 nitride layer comprising a plurality of monocrystalline particles having a particular crystal orientation in a normal direction,

wherein the group 13 nitride comprises gallium nitride, aluminum nitride, indium nitride or the mixed crystal thereof,

wherein the group 13 nitride layer comprises an upper surface and a bottom surface, and

wherein a full width at half maximum of a (1000) plane reflection on the upper surface is 20000 seconds or less and 1500 seconds or more.

The present invention further provides a free-standing substrate comprising the group 13 nitride layer.

The present invention further provides a functional device comprising:

the free-standing substrate; and

a functional layer provided on the group 13 nitride layer.

The present invention further provides a composite substrate comprising:

a supporting substrate; and

the group 13 nitride layer provided on the supporting substrate.

The present invention further provides a functional device comprising:

the composite substrate; and

a functional layer provided on the group 13 nitride layer.

The present invention further provides a method of producing a group 13 nitride layer, the method comprising the steps of:

film-forming an underlying layer comprising gallium nitride layer or alumina layer on a single crystal substrate;

forming a seed crystal film comprising a group 13 nitride on the underlying layer; and

providing a group 13 nitride layer comprising a polycrystalline group 13 nitride selected from gallium nitride, aluminum nitride, indium nitride or the mixed crystal thereof on the seed crystal layer, said group 13 nitride layer comprising a plurality of monocrystalline particles having a particular crystal orientation in a normal direction.

When it is produced a free-standing substrate composed of an oriented and polycrystalline group 13 nitride, the inventors have researched for further reducing dislocation defects or pits appeared on an upper surface of the free-standing substrate. As a result, the inventors focused on a twist component of the polycrystalline group 13 nitride crystal.

For example, as shown in FIG. 1(a), the oriented polycrystalline group 13 nitride layer 2 is composed of many monocrystalline particles 4 each extending in the direction of the thickness, and the crystal axes B of the respective monocrystalline particles are substantially aligned. On the other hand, as shown in FIG. 1(b), on an upper surface 2a of the group 13 nitride crystal layer 2, the directions of the crystal axes C and D of the respective monocrystalline particles 4 are usually random without particular orientation. According to such group 13 nitride crystal layer, the full width at half maximum of a (1000) plane reflection of the X-ray rocking curve on the upper surface is large and not measurable in the case of random orientation.

However, on the upper surface of such oriented group 13 nitride crystal layer, fine recesses (pits) tend to occur on the surface, and it is proved that the yield is reduced at some degree and luminous efficiency is thereby affected.

Contrary to this, according to the present invention, as shown in FIG. 2(b), the full width at half maximum of the (1000) plane reflection of the X-ray rocking curve on the upper surface 13a of the oriented group 13 nitride crystal layer 13 is made 20000 seconds or less. It means that the directions of the crystal axes C and D are aligned at some degree on the upper surface. It is proved that the surface pits described above were thereby reduced, the yield of the step of providing the functional layer thereon is improved and the efficiency of the functional layer is stabilized.

On the other hand, in the case that the group 13 nitride crystal layer is composed of a single crystal, although the number of the pits is small, it is difficult to reduce the dislocation defects penetrating through the layer from the underlying substrate at the upper surface, so that the dislocation defects is left on the upper surface at some degree. Contrary to this, according to the present invention, the full width at half maximum of the (1000) plane reflection of the X-ray rocking curve on the upper surface of the oriented group 13 nitride crystal layer is made 1500 seconds or higher, so that some degree of the twist component is left. It is thereby possible to reduce the dislocation defects on the upper surface of the group 13 nitride crystal layer.

### BRIEF DESCRIPTION OF THE DRAWINGS

FIG. 1(a) is a schematic view showing a cross section in which a group 13 nitride crystal layer 2 is formed on an oriented polycrystalline sintered body 1, and FIG. 1(b) is a schematic plan view showing the group 13 nitride crystal layer 2.

FIG. 2(a) is a schematic view showing a cross section in which an underlying layer 16, seed crystal layer 12 and group 13 nitride crystal layer 13 are formed on a single crystal substrate 11, and FIG. 2(b) is a schematic plan view showing the group 13 nitride crystal layer 13.

FIG. 3 is a cross sectional view schematically showing layered structure of a light-emitting device according to an embodiment of the present invention.

### MODES FOR CARRYING OUT THE INVENTION

The present invention will be described further in detail, appropriately referring to drawings.

First, it will be described a reference example in which the twist components on the upper surface of the oriented and polycrystalline group 13 nitride crystal layer are random.

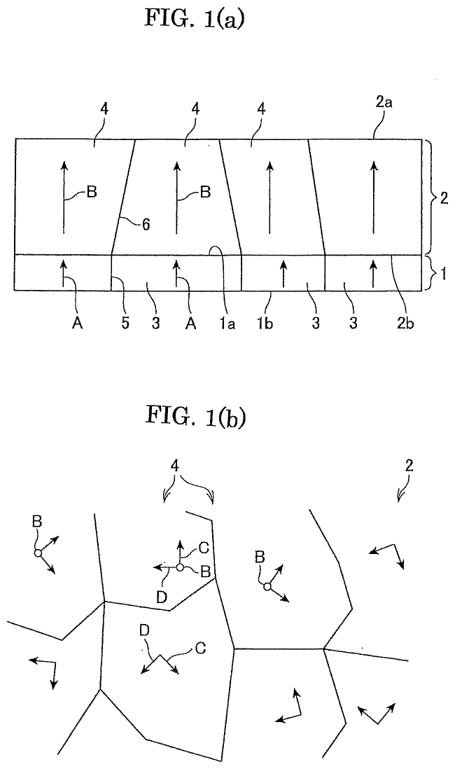

As schematically shown in FIG. 1(a), the oriented and polycrystalline sintered body 1 is composed of many monocrystalline particles 3, and a particle boundary is present between the adjacent monocrystalline particles 3, According to the oriented and polycrystalline sintered body, the crystal orientations of the monocrystalline particles 3 are not random and are aligned in a particular orientation. The degree of the crystalline orientation is called the degree of orientation. That is, as shown in FIG. 1(a), the crystal orientations A of the respective monocrystalline particles 3 are aligned at some degree. Further, preferably, the monocrystalline particles 3 extend between a first main surface 1a and a second main surface 1b of the oriented and polycrystalline sintered body. According to the present example, the first main surface 1a is made a crystal growth surface.

Then, a group 13 nitride crystal layer 2 is epitaxially grown on the growth surface 1a of the oriented polycrystalline sintered body 1. That is, the group 13 nitride crystal layer 2 is grown so as to have the crystal orientations approximately conforming to the crystal orientations of the oriented polycrystalline sintered body. 2b represents a growth initiation surface of the crystal layer 2, and 2a represents an upper surface of the crystal layer 2. The crystal layer 2 is composed of many monocrystalline particles 4, and an intergranular boundary 6 is present between the adjacent monocrystalline particles 4. In the crystal layer 2, the crystal orientations B of the monocrystalline particles 4 are not random and approximately conform to the orientations A of the respective monocrystalline particles 3 forming the oriented polycrystalline sintered body as the base layer.

However, according the cross section shown in FIG. 1(a), although the crystal orientations B of the respective monocrystalline particles 4 forming the group 13 nitride crystal layer 2 are aligned, the other crystal orientations of the monocrystalline particles 4 are not aligned. That is, as shown FIG. 1(b), in the case that the respective monocrystalline particles 4a reviewed in a plan view (from the direction parallel with the growth direction), the crystal orientations C and D are random and do not exhibit particular orientation. The full width at half maximum of the (1000) plane reflection on the upper surface is large and usually not measurable.

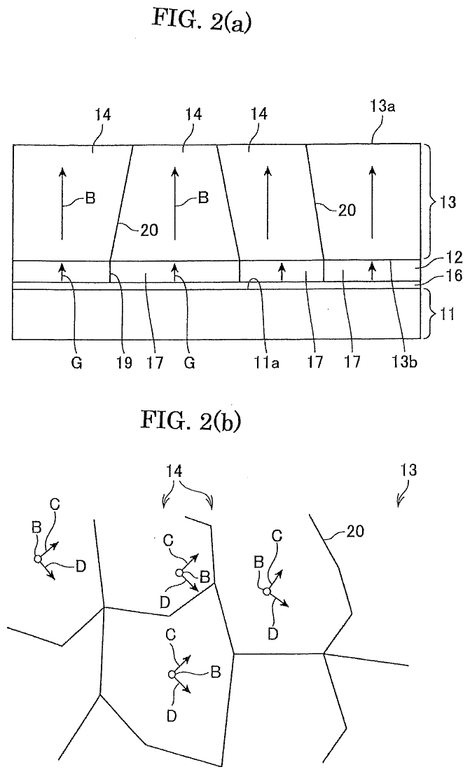

On the other hand, as shown in the inventive example of FIG. 2, an underlying layer 16 is provided as an initial layer on a growth surface 11a of a single crystal substrate 11, for example. Then, a seed crystal film 12 is provided on the underlying layer 16. The seed crystal film 12 is composed of many monocrystalline particles 17, and an intergranular boundary is present between the adjacent monocrystalline particles 17. In the seed crystal film 12, the crystal orientations of the monocrystalline particles are not random and are aligned in a particular direction. The degree of the orientation of the crystal directions is called an orientation degree. That is, as shown in FIG. 2(a), the crystal orientations G of the respective monocrystalline particles 17 are aligned at some degree. Further, preferably, the monocrystalline particles 17 are elongated between the first main surface and second main surface of the seed crystal film. According to the present example, the first main surface is selected as the crystal growth surface.

Then, a crystal layer 13 of the group 13 nitride is epitaxially grown on the growth surface of the seed crystal film 12. That is, the crystal layer 13 of the group 13 nitride is grown so as to have crystal orientations approximately conforming to the crystal orientations of the seed crystal film 12. 13b represents a growth initiation surface of the crystal layer 13 and 13a represents an upper surface of the crystal layer 13. The crystal layer 13 is composed of many monocrystalline particles 14, and an intergranular boundary 20 is present between the adjacent monocrystalline particles 14. In the crystal layer 13, the crystal orientations B of the monocrystalline particles 14 are not random and approximately conform to the orientations G of the respective monocrystalline particles forming the underlying seed crystal film.

At the same time, as shown in FIG. 2(b), in the case that the respective monocrystalline particles 14 forming the crystal layer 13 of the group 13 nitride are viewed from the upper surface (viewed in the direction parallel with the growth direction), the crystal orientations C and D are aligned at some degree. That is, the full width at half maximum of the (1000) plane reflection of the X-ray rocking curve on the upper surface of the crystal layer of the group 13 nitride is made 20000 seconds or less and 1500 seconds or more.

(Preferred Production Methods)

Preferred production methods of producing the crystal layer of the group 13 nitride of the present invention will be further described.

According to the present embodiment, a single crystal substrate is utilized as the underlying substrate.

Although the material forming the single crystal substrate is not limited, it includes sapphire, AlN template, GaN template, free-standing GaN substrate, silicon single crystal, SiC single crystal, MgO single crystal, spinel (MgAl₂O₄), LiAlO₂, LiGaO₂, and perovskite composite oxide such as LaAlO₃, LaGaO₃ or NdGaO₃ and SCAM (ScAlMgO₄). A cubic perovskite composite oxide represented by the composition formula [A_{1-y}(Sr₁₋ₓBaₓ)_{y}] [(Al_{1-z}Ga_{z})₁₋ᵤDᵤ]₃ (wherein A is a rare earth element; D is one or more element selected from the group consisting of niobium and tantalum; y=0.3 to 0.98; x=0 to 1; z=0 to 1; u=0.15 to 0.49; and x+z=0.1 to 2) is also applicable.

According to the present embodiment, the underlying layer is provided on the single crystal substrate.

Although the method of producing the underlying layer is not particularly limited, it is preferably listed a gas phase method such as MOCVD (metal organic chemical vapor deposition method), MBE (molecular beam epitaxy method), HVPE (hydride vapor phase epitaxy method), sputtering and the like, a liquid phase method such as sodium flux method, ammono-thermal method, hydrothermal method, sol-gel method and the like, a powder method utilizing the solid phase growth of powder and the combinations thereof. Sputtering method is particularly preferred.

Further, the material of the underlying layer is an oxide or a nitride. Alumina, gallium oxide, silicon oxide and zinc oxide may be exemplified as the oxide, silicon nitride may be exemplified as the nitride, and alumina and gallium oxide are preferred. Further, the materials of the underlying layer and single crystal substrate are preferably materials of the same kind or of the same composition.

The seed crystal film is then provided on the underlying layer. The material forming the seed crystal layer is made a nitride of one or two or more group 13 element(s) defined by IUPAC. The group 13 nitride is preferably gallium, aluminum or indium. Further, specifically, the crystal of the group 13 nitride is preferably GaN, AlN, InN, GaₓAl₁₋ₓN (1>x>0), GaₓIn₁₋ₓN (1>x>0), GaₓAl_{y}InN_{1-x-y} (1>x>0, 1>y>0).

Although the method of producing the seed crystal film is not particularly limited, it is preferably listed a gas phase method such as MOCVD (metal-organic chemical vapor deposition method), MBE (molecular beams epitaxy method), HVPE (hydride vapor phase epitaxy method), sputtering and the like, a liquid phase method such as sodium flux method, ammono-thermal method, hydrothermal method, sol-gel method and the like, a powder method utilizing the solid phase growth of powder and the combinations thereof.

For example, the formation of the seed crystal layer by MOCVD method is preferably performed by depositing a low-temperature growth interference GaN layer at 450 to 550° C. in 20 to 50 nm and by then growing a GaN film having a thickness of 2 to 4 μm at 1000˜1200° C.

The crystal layer of the group 13 nitride is formed so as to have crystal orientations approximately conforming to the crystal orientations of the seed crystal film. The method of forming the crystal layer of the group 13 nitride is not particularly limited, as far as it has the crystal orientations approximately conforming to the crystal orientations of the seed crystal film. It may preferably be listed a vapor phase method such as MOCVD and HVPE, a liquid phase method such as sodium flux method, ammono-thermal method, hydrothermal method, sol-gel method and the like, a powder method utilizing the solid phase growth of powder and the combinations thereof. It is particularly preferred to perform sodium flux method.

The formation of the crystal layer of the group 13 nitride by sodium flux method is preferably performed by filling, in a crucible with the seed crystal substrate provided therein, a melt composition containing a group 13 metal, sodium metal and optionally a dopant (for example, an n-type dopant such as germanium (Ge), silicon (Si), oxygen (O) or the like, or a p-type dopant such as beryllium (Be), magnesium (Mg), calcium (Ca)), strontium (Sr), zinc (Zn), cadmium (Cd) or the like), by raising the temperature to 830 to 910° C. and pressure to 3.5 to 4.5 MPa under nitrogen atmosphere and by then rotating the crucible while the temperature and pressure are maintained. Although the holding time period is different depending on the target film thickness, it may be made about 10 to 100 hours.

Further, the thus obtained group 13 nitride crystal obtained by sodium flux method may preferably be ground by grinding stones to flatten the plate face, followed by lapping using diamond abrasives to flatten the plate face.

(Separation of Crystal Layer of Group 13 Nitride)

The crystal layer of the group 13 nitride is then separated from the single crystal substrate so that a free-standing substrate including the crystal layer of the group 13 nitride is obtained.

Here, the method of separating the crystal layer of the group 13 nitride from the single crystal substrate is not limited. According to a preferred embodiment, the crystal layer of the group 13 nitride is spontaneously peeled off from the single crystal substrate in a temperature descending step after growing the crystal layer of the group 13 nitride.

Alternatively, the crystal layer of the group 13 nitride may be separated from the single crystal substrate by chemical etching.

As a etchant for performing the chemical etching, a strong acid such as sulfuric acid, hydrochloric acid or the like, or a strong alkali such as sodium hydroxide aqueous solution, potassium hydroxide aqueous solution or the like are preferred. The temperature for performing the chemical etching may preferably be 70° C. or higher.

Alternatively, the crystal layer of the group 13 nitride may be peeled off from the single crystal substrate by laser lift-off method.

Alternatively, the crystal layer of the group 13 nitride may be peeled-off from the single crystal substrate by grinding.

The crystal layer of the group 13 nitride may be separated from the single crystal substrate to obtain a free-standing substrate. The term “free-standing substrate” as used in the present invention means a substrate that are not be deformed or broken under its own weight during handling and can be handled as a solid. The free-standing substrate of the present invention can be used not only as a substrate for various types of semiconductor devices such as light emitting devices, but also as a member or a layer other than the base material, such as an electrode (which may be a p-type electrode or an n-type electrode), a p-type layer, or an n-type layer.

One or more of the other layer(s) may be further provided on the free-standing substrate.

(Composite Substrate)

The crystal layer of the group 13 nitride provided on the single crystal substrate may be used as a template substrate for forming another functional layer, without separating the crystal layer of the group 13 nitride.

(Polycrystalline Group 13 Nitride Layer)

The crystal layer of the group 13 nitride of the present invention is composed of a plurality of monocrystalline particles of the group 13 nitride oriented in the specific crystal orientation substantially in the direction of the normal line.

Preferably, the crystal layer of the group 13 nitride has an upper surface and bottom surface and the crystal orientations of the monocrystalline particles measured through inverse pole figure mapping of the electron back scatter diffraction (EBSD) on the upper surface are distributed in a manner inclined at various angles with respect to the particular crystal orientation (e.g. c-axis or a-axis orientation), and the average of the inclination angles may preferably be 0.1 degrees or higher and more preferably be 0.25 degrees or higher. Further, the average inclination angle may preferably be 5 degrees or lower, more preferably be 1 degree or lower, particularly preferably be 0.9 degrees or lower and most preferably be 0.8 degrees of lower.

Further, it is noted that the inclination angle as described herein may be referred to as tilt angle and the average inclination angle may be referred to as average tilt angle.

Preferably, the average cross-sectional diameter DT at the outermost surface of the monocrystalline particles exposed on the upper surface of the free-standing substrate is equal to or greater than 10 μm. It is noted that EBSD is a known method in which when a crystalline material is exposed to an electron beam, electron back scatter diffraction occurring on the upper surface of the sample causes Kikuchi line diffraction patterns, that is, EBSD patterns to be observed, whereby information of the crystal system and the crystal orientation of the sample can be obtained and, in combination with a scanning electron microscope (SEM), information of the distribution of the crystal system and the crystal orientation across small areas can also be obtained by measuring and analyzing EBSD patterns while scanning an electron beam.

A plurality of the monocrystalline particles forming the crystal layer of the group 13 nitride is oriented in the particular crystal orientation in approximately normal line direction. The particular crystal orientation may be any crystal orientation (e.g. c-plane or a-plane) that group 13 nitride can have. For example, if multiple monocrystalline particles are oriented in the c-plane in approximately the normal direction, each constituent particle at the upper surface of the substrate is to be arranged with the c-axis set in approximately the normal direction (i.e. the c-plane exposed on the upper surface of the substrate). The multiple monocrystalline particles of which the crystal layer of the group 13 nitride is composed have the particular crystal orientation in approximately the normal line direction, while the individual constituent particles are then slightly inclined at various angles. That is, while the entire upper surface of the substrate undergoes the predetermined particular crystal orientation in approximately the normal direction, the crystal orientations of the monocrystalline particles are distributed in a manner inclined at various angles with respect to the particular crystal orientation. As mentioned above, this specific state of orientation can be evaluated through inverse pole figure mapping of the EBSD on the upper surface (plate face) of the substrate. That is, the crystal orientations of the monocrystalline particles measured through inverse pole figure mapping of the EBSD on the upper surface of the substrate are distributed in a manner inclined at various angles with respect to the particular crystal orientation.

The crystal layer of the group 13 nitride preferably has a single crystal structure in approximately the normal line direction. In this case, the crystal layer of the group 13 nitride can be considered to be of a layer composed of multiple monocrystalline particles that have the single crystal structure in approximately the normal direction. That is, the crystal layer of the group 13 nitride is composed of multiple monocrystalline particles linked two-dimensionally in the horizontal direction and therefore can have the single crystal structure in approximately the normal line direction. Accordingly, the crystal layer of the group 13 nitride is not a single crystal on the whole, but has the single crystal structure per local domain unit.

Preferably, a plurality of the monocrystalline particles constituting the group 13 nitride crystal layer have crystal orientation that is mostly aligned in the approximately normal direction. The “crystal orientation that is mostly aligned in the approximately normal direction” is not necessarily limited to crystal orientation that is completely aligned in the normal direction, and means that it may be crystal orientation that is, to some extent, in alignment with the normal or a direction similar thereto as long as desired device properties of devices, such as light-emitting device, including the free-standing substrate can be ensured. Using an expression derived from the production method, it can also be said that the monocrystalline particles have a structure in which the particles are grown mostly in conformity with the crystal orientation of the seed crystal film used as a base substrate in producing the free-standing substrate. The “structure in which particles are grown mostly in conformity with the crystal orientation of the seed crystal film” means a structure resulting from crystal growth influenced by the crystal orientation of the seed crystal film, is not necessarily limited to a structure in which the particles are grown completely in conformity with the crystal orientation of the seed crystal film, and may be a structure in which particles are grown, to some extent, in conformity with the crystal orientation of the seed crystal film as long as desired device properties of devices can be ensured. That is, this structure also includes a structure in which the particles are grown in crystal orientation different from that of the seed crystal film. In this sense, the expression “structure in which particles are grown mostly in conformity with crystal orientation” can be paraphrased as “structure in which particles are grown in a manner mostly derived from crystal orientation”, and this paraphrasing and the above meaning similarly apply to similar expressions in this specification. Therefore, such crystal growth is preferably epitaxial growth, but it is not limited thereto, and may take a variety of similar crystal growth forms. In any case, with crystals grown in this way, the group 13 nitride crystal layer can have the structure in which the crystal orientation is mostly aligned with respect to the approximately normal direction.

It is noted that even when inverse pole figure mapping of the electron back scatter diffraction (EBSD) may be measured on the cross-section orthogonal to the upper surface of the crystal layer of the group 13 nitride, it is possible to recognize that the monocrystalline particles of which the crystal layer of the group 13 nitride is composed have the particular crystal orientation in approximately the normal direction.

Accordingly, the crystal layer of the group 13 nitride can be observed as a single crystal when viewed in the normal direction and can also be taken as a cluster of monocrystalline particles with a columnar structure in which particle boundaries are observed when viewed on the horizontal cross-section. Here, the term “columnar structure” does not mean only a typical vertically long columnar shape, but is defined as including various shapes such as horizontally long shape, trapezoidal shape, and upside-down trapezoidal shape. It will be appreciated that the structure of the crystal layer of the group 13 nitride is only required to have the crystal orientation aligned to some extent in the normal direction or its similar direction as described above, and a columnar structure in a strict sense is not necessarily required. Such a columnar structure is considered to be due to the fact that the monocrystalline particles grow under the influence of the crystal orientation of the oriented polycrystalline sintered body used for manufacturing of the group 13 nitride crystal layer as mentioned above. Thus, the average particle diameter of the cross-section (hereinafter referred to as average cross-sectional diameter) of each monocrystalline particle, which may have the columnar structure, may depend not only on film formation conditions, but also on the average particle diameter at the growth surface of the single crystal layer.

It is preferred that the monocrystalline particles exposed to the upper surface of the crystal layer of the group 13 nitride is communicated to the bottom surface of the crystal layer of the group 13 nitride without intervening particle boundaries. In the case that the particle boundaries are present, a resistance is provided in electrical conduction to result in a cause of reduction of each of the efficiencies.

According to the present invention, the crystal layer of the group 13 nitride includes an upper surface and bottom surface, and the full width at half maximum of (1000) plane reflection of the X-ray rocking curve on the upper surface is 20000 seconds or less and 1500 seconds or more. The full width at half maximum of the (1000) plane reflection of the X-ray rocking curve on the upper surface is 20000 seconds or less, and preferably 10000 seconds or less and still more preferably be 5000 seconds or less. Further, the full width at half maximum of the (1000) plane reflection of the X-ray rocking curve on the upper surface is 1500 seconds or more, preferably be 2000 seconds or more and more preferably 2500 seconds or more.

Incidentally, the average cross-sectional diameter DT at the outermost surfaces of the monocrystalline particles exposed on the upper surface of the crystal layer of the group 13 nitride is preferably different from the average cross-sectional diameter DB at the outermost surfaces of the monocrystalline particles exposed on the bottom surface of the crystal layer of the group 13 nitride. For example, a 13-group element nitride crystal, when epitaxially grown thorough gas phase and/or liquid phase, grows not only in the normal direction but also in the horizontal direction, though depending on film formation conditions. In this case, if there is a variation in the quality of particles from which the growth starts and/or a seed crystal fabricated thereon, the individual single crystals have their respective different growth rates and particles growing at higher rate may grow in a manner covering particles growing at lower rate. In the case of such a growth behavior, particles at the upper surface of the substrate are more likely to have a large diameter than at the bottom surface of the substrate. In this case, slowly growing crystals stop growing in the middle, and particle boundaries can be observed also in the normal direction when viewed on one cross-section. However, particles exposed on the upper surface of the substrate communicate with the bottom surface of the substrate with no particle boundary therebetween, providing no resistive phase when applying a current. In other words, since dominant ones of the particles exposed on the upper surface of the substrate after gallium nitride crystal film formation communicate with the bottom surface with no particle boundary therebetween, it is preferable to fabricate a light emitting functional layer on the upper surface of the substrate in terms of increase in the luminous efficiency of a vertically-structured LED. On the other hand, since the bottom surface of the crystal layer of the group 13 nitride also has a mix of particles not communicating with the upper surface of the substrate, fabricating a light emitting functional layer on the bottom surface of the substrate may cause reduction in the luminous efficiency.

Accordingly, in the case of a growth behavior in which particles at the upper surface of the crystal layer of the group 13 nitride have a larger diameter than particles at the bottom surface, that is, the average cross-sectional diameter of monocrystalline particles exposed on the upper surface of the crystal layer of the group 13 nitride is larger than the average cross-sectional diameter of monocrystalline particles exposed on the bottom surface, the efficiency preferably increases (this can be translated into the state that the number of monocrystalline particles exposed on the upper surface of the crystal layer of the group 13 nitride is preferably smaller than the number of monocrystalline particles exposed on the bottom surface).

Specifically, the ratio DT/DB between the average cross-sectional diameter at the outermost surface of the monocrystalline particles exposed on the upper surface of the crystal layer of the group 13 nitride (hereinafter referred to as average cross-sectional diameter DT at the upper surface of the substrate) and the average cross-sectional diameter at the outermost surface of the monocrystalline particles exposed on the bottom surface of the crystal layer of the group 13 nitride (hereinafter referred to as average cross-sectional diameter DB at the bottom surface of the substrate) is preferably greater than 1.0, preferably equal to or greater than 1.1, more preferably equal to or greater than 1.5, further preferably equal to or greater than 2.0, particularly preferably equal to or greater than 3.0, and most preferably equal to or greater than 5.0. However, when the ratio DT/DB is too high, the efficiency may be lowered. The ratio may preferably be 20 or less and more preferably be 10 or less. If the ratio DT/DB is too high, particles communicating between the upper surface and the bottom surface of the substrate (i.e. particles exposed on the upper surface of the substrate) have a smaller cross-sectional diameter in the vicinity of the bottom surface of the substrate. This may result in an insufficient current path to cause reduction in the luminous efficiency, though details are not known.

Further, the average cross-sectional diameter DT at the outermost surface of the monocrystalline particles exposed on the upper surface of the crystal layer of the group 13 nitride is equal to or greater than 10 μm, preferably equal to or greater than 20 μm, more preferably equal to or greater than 50 μm, particularly preferably equal to or greater than 70 μm, and most preferably equal to or greater than 100 μm. The upper limit of the average cross-sectional diameter of the monocrystalline particles at the upper surface of the crystal layer of the group 13 nitride is realistically equal to or smaller than 1000 μm, more realistically equal to or smaller than 500 μm, still more realistically equal to or smaller than 200 μm, though not particularly limited thereto.

The nitride forming the crystal layer of the group 13 nitride is gallium nitride, aluminum nitride, indium nitride or the mixed crystals thereof. Specifically, it may be GaN, AlN, InN, GaₓAl₁₋ₓN (1>x>0), GaₓIn₁₋ₓN (1>x>0), or GaₓAl_{y}InN_{1-x-y} (1>x>0, 1>y>0).

More preferably, the nitride forming the crystal layer of the group 13 nitride is a gallium nitride-based nitride. Specifically, it is GaN, GaₓAl₁₋ₓN (1>x>0.5), GaₓIn₁₋ₓN (1>x>0.4), or GaₓAl_{y}In_{z}N (1>x>0.5, 1>y>0.3, x+y+z=1).

The polycrystalline group 13 nitride forming the free-standing substrate may be further doped with a n-type dopant or p-type dopant in addition to zinc and calcium. In this case, the polycrystalline group 13 nitride may be used as a member or a layer other than the base material, such as a p-type electrode, or an n-type electrode, a p-type layer, or an n-type layer. A preferable example of the p-type dopant may be one type or more selected from the group consisting of beryllium (Be), magnesium (Mg), strontium (Sr) and cadmium (Cd). A preferable example of the n-type dopant may be one type or more selected from the group consisting of silicon (Si), germanium (Ge), tin (Sn), and oxygen (O).

In the case that the group 13 crystal layer forms the free-standing substrate, the free-standing substrate must have a thickness that allows for free standing and preferably has a thickness of 20 μm or more, more preferably 100 μm or more, and further preferably 300 μm or more. No upper limit should be set on the thickness of the free-standing substrate, but it is realistic to have a thickness of 3000 μm or less in terms of manufacturing cost.

The aspect ratio T/DT, which is defined as a ratio between the thickness T of the free-standing substrate with respect to the average cross-sectional diameter DT at the outermost surface of the monocrystalline particles exposed to the upper surface of the crystal layer of the group 13 nitride, is preferably equal to or greater than 0.7, more preferably equal to or greater than 1.0, and further preferably equal to or greater than 3.0. This aspect ratio is preferred in terms of increase in the efficiency of a functional device.

Further, the resistivity of the crystal layer of the group 13 nitride may preferably be 30 mΩ·cm or lower and more preferably 15 Ω·cm or lower.

(Functional Device)

Although a functional device structure provided on the crystal layer of the group 13 nitride of the invention is not particularly limited, it may be listed light-emitting function, rectifying function or electric-power controlling function.

The structure and fabricating method of the light emitting device using the crystal layer of the group 13 nitride of the invention is not particularly limited. Typically, the light emitting device is fabricated by providing a light emitting functional layer on the crystal layer of the group 1 nitride, and the light emitting functional layer is preferably formed to have a crystal orientation generally following the crystal orientation of the group 13 nitride crystal layer, by forming one or more layers composed of multiple monocrystalline particles that have a single crystal structure in approximately the normal direction. It will be appreciated that the light emitting device may be fabricated by utilizing the polycrystalline crystal layer of the group 13 nitride as a member or a layer other than the base material, such as an electrode (which may be a p-type electrode or an n-type electrode), a p-type layer, or an n-type layer.

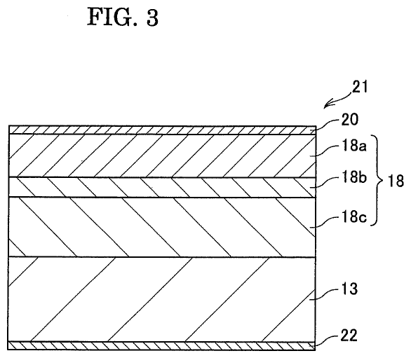

FIG. 3 schematically shows the layer configuration of a light emitting device according to an aspect of the present invention. The light emitting device 21 shown in FIG. 3 includes a free-standing substrate 13 and a light emitting functional layer 18 formed on the substrate. The light emitting functional layer 18 has at least one layer having a single crystal structure in approximately the normal direction and are composed of multiple semiconductor monocrystalline particles. The light emitting functional layer 18 provides light emission based on the principle of light emitting devices such as LEDs by appropriately providing electrodes thereon and applying a voltage therebetween.

The light emitting functional layer 18 is formed on the substrate 13. The light emitting functional layer 18 may be provided entirely or partially on the surface of the substrate 13 or may be provided entirely or partially on the surface of a buffer layer to be described hereinafter if formed on the substrate 13. The light emitting functional layer 18 has one or more layers composed of multiple semiconductor monocrystalline particles that have a single crystal structure in approximately the normal direction and may take one of various known layer configurations that provides light emission based on the principle of light emitting devices as represented by LEDs by appropriately providing electrodes and/or phosphors thereon and applying a voltage therebetween. Accordingly, the light emitting functional layer 18 may emit visible light of, for example, blue and red or may emit ultraviolet light without or with the visible light. The light emitting functional layer 18 preferably forms at least part of a light emitting device that exploits a p-n junction and the p-n junction may include an active layer 18b between a p-type layer 18a and an n-type layer 18c, as shown in FIG. 3. In this case, a double heterojunction or a single heterojunction (hereinafter referred to collectively as heterojunction) may be employed in which the active layer has a bandgap lower than that of the p-type layer and/or the n-type layer. A quantum well structure in which the active layer is thinned may also be taken as one form of p-type layer/active layer/n-type layer. A double heterojunction in which the active layer has a bandgap lower than that of the p-type layer and the n-type layer should obviously be employed to obtain a quantum well. Many quantum well structures may also be stacked to provide a multiple quantum well (MQW) structure. These structures allow to have a higher luminous efficiency compared to p-n junction. The light emitting functional layer 18 thus preferably includes a p-n junction, a heterojunction, and/or a quantum well junction having a light emitting function. Further, 20 and 22 represent examples of electrodes.

Accordingly, one or more layers forming the light emitting functional layer 18 can include at least one or more selected from the group consisting of the n-type layer with n-type dopants doped therein, the p-type layer with p-type dopants doped therein, and the active layer. In the n-type layer, the p-type layer, and the active layer (if exists), the main component may be of the same material or may be of respectively different materials.

The material of each layer forming the light emitting functional layer 18 is not particularly limited as long as grown in a manner generally following the crystal orientation of the crystal layer of the group 13 nitride and having a light emitting function, but preferably includes one type or more selected from gallium nitride (GaN)-based material, zinc oxide (ZnO)-based material, and aluminum nitride (AlN)-based material as the main component and may appropriately contain dopants for controlling to be p-type or n-type. Gallium nitride (GaN)-based material is particularly preferable. The material of the light emitting functional layer 18 may be a mixed crystal with, for example, AlN, InN, etc. solid-solved in GaN to control the bandgap. As mentioned in the last paragraph, the light emitting functional layer 18 may employ a heterojunction composed of multiple types of material systems. For example, the p-type layer may employ gallium nitride (GaN)-based material, while the n-type layer may employ zinc oxide (ZnO)-based material. Alternatively, the p-type layer may employ zinc oxide (ZnO)-based material, while the active layer and the n-type layer may employ gallium nitride (GaN)-based material, the combination of materials being not particularly limited.

The film formation method for the light emitting functional layer 18 and the buffer layer is preferably exemplified by a gas phase method such as MOCVD, MBE, HVPE, and sputtering, a liquid phase method such as sodium flux method, ammono-thermal method, hydrothermal method, and sol-gel method, a powder method utilizing the solid phase growth of powder, and combinations thereof, though not particularly limited as long as being grown in a manner generally following the crystal orientation of the crystal layer of the group 13 nitride.

### EXAMPLES

### Inventive Example 1

It was grown the crystal layer of the group 13 nitride of the inventive example, according to the method described referring to FIG. 2.

### (Growth of Alumina Layer and Seed Crystal Film)

Specifically, it was formed an alumina layer 16 having a thickness of 1500 angstrom by sputtering on a C-plane monocrystalline sapphire substrate 11. Specifically, the film-formation was performed by RF magnetron sputtering method at an RF power of 500 W and at a pressure of 1 Pa, by using alumina (purity of 99 percent or higher) as a target and by flowing argon as a process gas (flow rate of 20 sccm), while the C-plane monocrystalline sapphire substrate 11 was heated at 500° C.

It was then formed the seed crystal layer 12 on the alumina layer 16 by applying MOCVD method. Specifically, a low-temperature GaN layer was formed at 530° C. in 40 nm, followed by depositing a GaN layer at 1050° C. in a thickness of 3 μm to obtain a seed crystal substrate.

(Film Formation of a Ge-Doped GaN Layer by Sodium Flux Method)

The seed crystal substrate fabricated in the step above was installed at the bottom of a cylindrical flat-bottomed alumina crucible with an inside diameter of 80 mm and a height of 45 mm, and the crucible was then filled with a melt composition in a glove box. The composition of the melt composition was as follows:

metallic Ga: 60 g

metallic Na: 60 g

germanium tetrachloride: 1.85 g.

The alumina crucible was put and sealed in a heat-resistant metal container, which was then installed on a pedestal capable of rotation in a crystal growing furnace. After increasing the temperature and pressure to 870° C. and 4.0 MPa in nitrogen atmosphere, the solution was rotated with the condition maintained for 50 hours to grow a gallium nitride crystal layer 13 while stirring. After the crystal growth, three hours were taken for slow cooling back to room temperature and the growing container was taken out of the crystal growing furnace. Ethanol was used to remove the melt composition remaining in the crucible and the sample with a gallium nitride crystal grown therein was recovered. In the resulting sample, a Ge doped gallium nitride crystal was grown on the entire surface of 60-mm seed crystal substrate with the crystal having a thickness of 600 μm. No crack was seen.

(Laser Lift-Off)

The gallium nitride crystal layer 13 was then separated from the sapphire substrate 11 by laser lift-off method to obtain a free-standing substrate. Specifically, laser light of a wavelength of 355 nm was irradiated from the side of the sapphire substrate.

(Surface Processing of Free-Standing Substrate)

The upper surface and bottom surface of the free-standing substrate were ground by grinding stones of #600 and #2000 to flatten the plate surface. The plate surface was then smoothened by lapping using diamond grinding stones to obtain a Ge-doped gallium nitride free-standing substrate having a thickness of about 300 μm. Meanwhile, during the flattening process, the sizes of the grinding stones were made smaller stepwise from 3 μm to 0.1 μm to improve the flatness. The average roughness Ra of the surface of the gallium nitride free-standing substrate after the processing was 0.2 nm.

(Measurement of Dislocation Density)

Then, as to the upper surface of the group 13 nitride crystal layer, dark spots on the uppermost surface of the thus obtained free-standing substrate was counted by cathode luminescence (CL) to calculate the dislocation density. As a result, dislocations were not counted and pits were not observed in a measurement visual field (80×105 μm).

(Full Width at Half Maximum of (1000) Plane Reflection of X-Ray Rocking Curve on Upper Surface)

It was measured the full width at half maximum of the (1000) plane reflection of X-ray rocking curve at the upper surface of the group 13 nitride crystal layer, as described below.

As a result, the full width at half maximum of the (1000) plane reflection was proved to be 15200 arcsec (seconds).

(Film-Formation of Light-Emitting Functional Layer by MOCVD Method)

It was deposited a GaN layer in 1 μm as an n-type layer at 1050° C. doped so as to have an Si atomic concentration of 5×10¹⁸/cm³ by MOCVD method on the gallium nitride free-standing substrate. It was then deposited multiple quantum well layers at 750° C. as a light-emitting layer. Specifically, it was alternately deposited five layers of well layers each in 2.5 nm of InGaN and six layer of barrier layers each in 10 nm of GaN. It was then deposited p-GaN in 200 nm as a p-type layer at 950° C. doped so as to have an Mg atomic concentration of 1×10¹⁹/cm³. Thereafter, it was taken out of the MOCVD apparatus and subjected to thermal treatment at 800° C. in nitrogen atmosphere for 10 minutes as activation treatment of Mg ions in the p-type layer.

(Production of Light-Emitting Device)

Cathode electrodes of Ti/Al/Ni/Au films were patterned in thicknesses of 15 nm, 70 nm, 12 nm and 60 nm, respectively, by applying photolithography process and vacuum vapor deposition method on a surface on the opposite side of the n-GaN layer and the p-GaN layer of the gallium nitride free-standing substrate. Thereafter, thermal treatment was performed for 30 seconds at 700° C. under nitrogen atmosphere, for making ohmic contact characteristics better. Further, Ni/Al films were patterned in thicknesses of 6 nm and 12 nm, respectively, as translucent anode electrode on the p-type layer, by photography process and vacuum vapor deposition. Thereafter, for making the ohmic contact characteristics better, thermal treatment was performed under nitrogen atmosphere at 500° C. for 30 minutes. Further, Ni/Au films were patterned in thicknesses of 5 nm and 60 nm, respectively, as an anode electrode pad on a partial region of the upper surface of the Ni/Al films as the translucent anode electrode by applying photolithography process and vacuum vapor deposition. The thus obtained substrate was cut into chips, which were then mounted on lead frames to obtain light emitting devices of vertical type structure.

(Evaluation of Light-Emitting Device)

100 counts of samples arbitrarily selected from the produced device were subjected to I-V measurement by flowing current between the cathode and anode electrodes, and rectifying property was confirmed in the 92 counts. Further, as a current is flown in forward direction, it was confirmed light emission of a wavelength of 460 nm.

### Comparative Example 1

The group 13 nitride crystal layer was grown, according to the method described referring to FIG. 1.

(Production of c-Plane Oriented Alumina Sintered Body)

As a raw material, a plate-shaped alumina powder (manufactured by Kinsei Matec Co., Ltd., grade 00610) was provided. 7 parts by weight of a binder (polyvinyl butyral: lot number BM-2, manufactured by Sekisui Chemical Co., Ltd.), 3.5 parts by weight of a plasticizer (DOP: di(2-ethylhexyl) phthalate, manufactured by Kurogane Kasei Co., Ltd.), 2 parts by weight of a dispersing agent (Rheodol SP-030, manufactured by Kao Corporation), and a dispersion medium (2-ethylhexanol) were mixed with 100 parts by weight of the plate-shaped alumina particles. The amount of the dispersion medium was adjusted so that the slurry viscosity was made 20000 cP. The slurry prepared as above was formed into a sheet on a PET film by a doctor blade method so as to have a dry thickness of 20 μm. The resulting tape was cut into circles each having a diameter of 50.8 mm (2 inches), then 150 pieces were stacked and placed on an Al plate having a thickness of 10 mm, and then vacuum packing was performed. This vacuum pack was subjected to isostatic pressing in hot water at 85° C. under a pressure of 100 kgf/cm², and a disc-shaped green body was obtained.

The resulting green body was placed in a degreasing furnace and degreased at 600° C. for 10 hours. The resulting degreased body was fired by hot pressing at 1600° C., for 4 hours under a surface pressure of 200 kgf/cm² in nitrogen using a graphite mold. The resulting sintered body was re-fired at 1700° C. for 2 hours under a gas pressure of 1500 kgf/cm² in argon by hot isostatic press-sintering method (HIP).

The sintered body obtained in this way was fixed to a ceramic surface plate and ground to #2000 using grinding wheel to flatten the plate surface. Next, the plate surface was smoothened by lapping using diamond abrasive particles to obtain an oriented alumina sintered body having a diameter of 60 mm and a thickness of 1 mm as an oriented alumina substrate. Flatness was improved by reducing the sizes of abrasive particles from 3 μm to 0.5 μm in a stepwise manner. The average roughness Ra after the processing was 1 nm.

(Film-Formation of Seed Crystal Film)

Then, the seed crystal film was formed according to the same procedure as the inventive example 1, on the processed oriented alumina substrate by applying MOCVD method.

(Film-Formation and Processing of Ge-Doped GaN Layer by Sodium Flux Method)

The gallium nitride layer was film-formed according to the same procedure as that of the inventive example 1, on the seed crystal film. The thickness of the gallium nitride layer was made 1.4 mm. Cracks were not observed.

The oriented alumina substrate of the thus obtained sample was removed according to the same procedure as that of the inventive example 1. The upper surface and bottom surface of the thus obtained free-standing substrate were processed according to the same procedure as that of the inventive example 1.

(Measurement of Dislocation Density)

The dark spots on the uppermost surface of the thus obtained free-standing substrate were counted by cathode luminescence, according to the same procedure as that of the inventive example 1. Dislocations were not counted and pits were not observed, in the visual field (80×105 μm) to be measured.

(Full Width at Half Maximum of (1000) Plane Reflection of X-Ray Rocking Curve on Upper Surface)

It was measured the full width at half maximum of the (1000) plane reflection of the X-ray rocking curve on the upper surface of the group 13 nitride crystal layer, according to the same procedure as that of the inventive example 1.

As a result, peaks were not confirmed and the full width at half maximum could not be measured.

(Production and Evaluation of Light-Emitting Device)

The light-emitting device was produced on the upper surface of the free-standing substrate, according to the same procedure as that of the inventive example 1.

100 counts of samples arbitrarily selected from the produced device were subjected to I-V measurement by flowing current between the cathode and anode electrodes, and rectifying property was confirmed in the 80 counts. Further, as a current is flown in forward direction, it was confirmed light emission of a wavelength of 460 nm.

As to the reasons why the yield is lower than that of the inventive example 1, it is considered that twist components of the crystal are more aligned in the inventive example 1 so that the generation of fine pits capable of resulting in defects in the device is suppressed.

### Comparative Example 2

It was grown the seed crystal film of gallium nitride on the sapphire substrate by MOCVD method according to same procedure as the inventive example 1. It was then grown the Ge-doped gallium nitride crystal layer (thickness of 600 μm) by sodium flux method according to the same procedure as the inventive example 1. The sapphire substrate was then removed by laser lift-off method according to the same procedure as that of the inventive example 1, and the upper and bottom surfaces of the free-standing substrate composed of the thus obtained group 13 nitride crystal layer were subjected to polishing.

(Measurement of Dislocation Density)

Dark spots on the uppermost surface of the thus obtained free-standing substrate were counted by cathode luminescence, according to the same procedure as that of the inventive example 1. As a result, the dislocation density was proved to be 2.1×10⁶ cm⁻² in the visual field (80×105 μm) to be measured.

(Full Width at Half Maximum of (1000) Plane Reflection of X-Ray Rocking Curve on Upper Surface)

It was measured the full width at half maximum of the (1000) plane reflection of the X-ray rocking curve on the upper surface of the group 13 nitride crystal layer, according to the same procedure as that of the inventive example 1. As a result, the full width at half maximum was proved to be 640 arcsec (seconds).

(Production and Evaluation of Light-Emitting Device)

The light-emitting device was produced on the upper surface of the free-standing substrate, according to the same procedure as that of the inventive example 1.

100 counts of samples arbitrarily selected from the produced devices were subjected to I-V measurement by flowing current between the cathode and anode electrodes, and rectifying property was confirmed in the 90 counts. Further, as a current is flown in forward direction, it was confirmed light emission of a wavelength of 460 nm.

(Comparison of Luminous Intensity)

The average luminous intensities of 100 counts of devices were measured and compared for to the LED's of the respective examples to prove to be 1.00:0.82:0.63 for the inventive example 1, comparative example 1, and comparative example 2.

Dislocations could not be confirmed in the visual fields in both of the inventive example 1 and comparative example 1. It is considered that the area of intergranular boundaries is smaller in the inventive example 1 and the dislocation density of the thus produced LED layer tends to be lower, contributing to the improvement of the luminous efficiency. Further, in the case that the inventive example 1 and comparative example 2 were compared with each other, it is considered that the difference of the dislocation densities affects the luminous intensities. Although the full width at half maximum of the (1000) plane reflection is lower in the free-standing substrate of the comparative example 2 than that of the inventive example 1, it is considered that, as far as the twist component is aligned as in the inventive example 1, it was not formed the pits substantially affecting the device when the light-emitting device is formed thereon.

### Inventive Example 2

It was produced the free-standing substrate of gallium nitride crystal layer, according to the same procedure as that of the inventive example 1. However, the full width at half maximum of the (1000) plane reflection of the X-ray rocking curve on the upper surface of the free-standing substrate according to the inventive example 2 was proved to be 11100 arcsec (seconds).

Meanwhile, the full width at half maximum could be adjusted by changing the thickness of the alumina layer by the sputtering as shown below.

Inventive example 1: 1500 angstrom
Inventive example 2: 1000 angstrom
Inventive example 3: 500 angstrom
Inventive example 4: 150 angstrom

Dark spots on the uppermost surface of the thus obtained free-standing substrate was counted by cathode luminescence, according to the same procedure as that of the inventive example 1. As a result, the dislocation was not counted and pits were not observed, in the visual field (80×105 μm) to be measured.

100 counts of samples arbitrarily selected from the produced devices were subjected to I-V measurement by flowing current between the cathode and anode electrodes, and rectifying property was confirmed in the 93 counts. Further, as a current is flown in forward direction, it was confirmed light emission of a wavelength of 460 nm.

Further, provided that 1.00 is assigned to the luminous intensity of the device of the inventive example 1, the luminous intensity of the device of the present example was proved to be 1.02.

### Inventive Example 3

It was produced the free-standing substrate of gallium nitride crystal layer, according to the same procedure as that of the inventive example 1. However, the full width at half maximum of the (1000) plane reflection of the X-ray rocking curve on the upper surface of the free-standing substrate according to the inventive example 3 was proved to be 7500 arcsec (seconds).

Dark spots on the uppermost surface of the thus obtained free-standing substrate was counted by cathode luminescence, according to the same procedure as that of the inventive example 1. As a result, the dislocation was not counted and pits were not observed, in the visual field (80×105 μm) to be measured.

Further, the light-emitting device was produced on the upper surface of the free-standing substrate.

100 counts of samples arbitrarily selected from the produced devices were then subjected to I-V measurement by flowing current between the cathode and anode electrodes, and rectifying property was confirmed in the 89 counts. Further, as a current is flown in forward direction, it was confirmed light emission of a wavelength of 460 nm.

Further, provided that 1.00 is assigned to the luminous intensity of the device of the inventive example 1, the luminous intensity of the device of the present example was proved to be 0.94.

### Inventive Example 4

It was produced the free-standing substrate of gallium nitride crystal layer, according to the same procedure as that of the inventive example 1. However, the full width at half maximum of the (1000) plane reflection of the X-ray rocking curve on the upper surface of the free-standing substrate according to the inventive example 4 was proved to be 1650 arcsec (seconds).

Dark spots on the uppermost surface of the thus obtained free-standing substrate was counted by cathode luminescence, according to the same procedure as that of the inventive example 1. As a result, the dislocation density was proved to be 1.1×10⁴ cm⁻² in the visual field (80×105 μm) to be measured.

Further, the light-emitting device was produced on the upper surface of the free-standing substrate, according to the same procedure as the inventive example 1.

100 counts of samples arbitrarily selected from the produced devices were then subjected to I-V measurement by flowing current between the cathode and anode electrodes, and rectifying property was confirmed in the 91 counts. Further, as a current is flown in forward direction, it was confirmed light emission of a wavelength of 460 nm.

Further, provided that 1.00 is assigned to the luminous intensity of the device of the inventive example 1, the luminous intensity of the device of the present example was proved to be 0.85.

### Inventive Example 5

The volume resistivity of the free-standing substrate of the inventive example 1 was measured by hall effect measurement to prove that it was of n-type and the volume resistivity was 4 mΩ·cm.

### Inventive Example 6

The free-standing substrate was produced according to the same procedure as the inventive example 1.

However, different from the inventive example 1, Mg was doped when the gallium nitride layer was film-formed by sodium flux method.

The nitride layer of the thus obtained free-standing substrate was measured by Hall effect measurement to prove to be of p-type.

### Inventive Example 7

The free-standing substrate was produced according to the same procedure as the inventive example 1.

However, different from the inventive example 1, zinc was used as a dopant when the gallium nitride layer was film-formed by sodium flux method.

As the volume resistivity of the thus obtained free-standing substrate was measured by Hall effect measurement, it wad of n-type and the volume resistivity was proved to be 6×10⁶ Ω·cm, providing a higher resistance.

### Inventive Example 8

It was produced a functional device having rectifying function.

That is, a Schottky diode barrier structure was film-formed on the upper surface of the free-standing substrate obtained in the inventive example 1, as follows. Electrodes were then formed to obtain a diode and the characteristics were confirmed.

(Film-Formation of Layer Having Rectifying Function by MOCVD Method)

It was film-formed n-GaN layer in 1 μm doped so as to have an Si atom concentration of 1×10¹⁷/cm³ as an −n-type layer at 1050° C. on the free-standing substrate by applying MOCVD (organic metal chemical vapor deposition) method.

(Production of Rectifying Device)

Ti/Al/Ni/Au films were patterned in thicknesses of 15 nm, 70 nm, 12 nm and 60 nm, respectively, as an ohmic electrode on a surface on the opposite side of the n-GaN layer on the free-standing substrate, by applying photolithography process and vacuum vapor deposition method. Thereafter, for assuring good ohmic contact characteristics, thermal treatment was performed at 700° C. under nitrogen atmosphere for 30 seconds. Further, by applying photolithography process and vacuum vapor deposition method. Ni/Au films were patterned in thicknesses of 6 nm and 80 nm, respectively, as a Schottky electrode on the n-GaN layer film-formed by MOCVD method. The thus obtained substrate was cut into chips, which were then mounted on lead frames to obtain rectifying devices.

(Evaluation of Rectifying Device)

I-V measurement was performed to confirm the rectifying characteristics.

### Inventive Example 9

It was produced a functional device having function of controlling electric power.

It was produced the free-standing substrate according to the same procedure as the inventive example 1. However, different from the inventive example 1, impurities were not doped during the film-formation of the gallium nitride crystal by sodium flux method.

Al_{0.3}Ga_{0.7}N/GaN HEMT structure was film-formed on the upper surface of the thus obtained free-standing substrate by MOCVD method as follows, electrodes were then formed and transistor characteristics was confirmed.

(Film-Formation of Layer Having Electric Power-Controlling Function by MOCVD Method)

It was formed a GaN layer without doping of impurities in 3 μm as an i-type layer at 1050° C. on the free-standing substrate by applying MOCVD (metal organic chemical vapor deposition) method. Al_{0.25}Ga_{0.75}N layer was then film-formed as a functional layer at the same 1050° C. in 25 nm. It was thereby obtained Al_{0.25}Ga_{0.75}N/GaN HEMT structure.

(Production of Electric Power-Controlling Device)

Ti/Al/Ni/Au films were patterned in thicknesses of 15 nm, 70 nm, 12 nm and 60 nm, respectively, as source and drain electrodes by applying photography process and vacuum vapor deposition method. Thereafter, for assuring good ohmic contact characteristic, thermal treatment was performed under nitrogen atmosphere at 700° C. for 30 seconds. Further, Ni/Au films were formed and patterned in thicknesses of 6 nm and 80 nm, respectively, as a gate electrode through Schottky junction by applying photolithography process and vacuum vapor deposition method. The thus obtained substrate was cut into chips, which were then mounted on lead frames to obtain devices of controlling electric power.

(Evaluation of Electric Power Controlling Device)

As I-V characteristics was measured, good pinch-off characteristics was confirmed and obtained, so that the maximum drain current was 860 mA/mm and the maximum transconductance was 290 mS/mm.

### Inventive Example 10

It was grown the group 13 nitride crystal layer of the inventive example according to the same procedure as that of the inventive example 1.

However, specifically, it was formed the gallium oxide layer 16 having a thickness of 1000 angstrom on the C-plane monocrystalline sapphire substrate 11 by sputtering method. The film-formation was performed by applying RF magnetron sputtering method, at an RF power of 500 W, at a pressure of 1 Pa, by using gallium oxide (purity of 99 percent or higher) as a target, and by flowing argon (15 sccm) and oxygen (5 sccm) as process gases, while the C-plane monocrystalline sapphire substrate 11 was heated at 500° C.

Then, the seed crystal layer 12 was formed on the gallium oxide layer 16 by MOCVD method to obtain the seed crystal substrate, according the same procedure as the inventive example 1. The Ge-doped GaN layer was then film-formed by sodium flux method.

The upper surface of the group 13 nitride crystal layer was then subjected to cathode luminescence (CL) to count the dark spots on the uppermost surface of the thus obtained free-standing substrate, so that the dislocation density was calculated. As a result, dislocation was not counted and pits were no observed in the visual field (80×105 μm) to be measured.

It was further measured the full width at half maximum of the (1000) plane reflection of the X-ray rocking curve on the upper surface of the group 13 nitride crystal layer to obtain a value of 16500 arcsec.

Further, the light-emitting devices were produced by MOCVD method according to the same procedure as the inventive example 1. 100 counts of samples arbitrarily selected from the produced devices were subjected to I-V measurement by flowing current between the cathode and anode electrodes, and rectifying property was confirmed in the 90 counts. Further, as a current is flown in forward direction, it was confirmed light emission of a wavelength of 460 nm.

Further, provided that 1.00 is assigned to the luminous intensity of the device of the inventive example 1, the luminous intensity of the device of the present example was proved to be 0.97.

1. A group 13 nitride layer comprising a polycrystalline group 13 nitride,
said group 13 nitride layer comprising a plurality of monocrystalline particles having a particular crystal orientation approximately in a normal direction,
wherein said group 13 nitride comprises gallium nitride, aluminum nitride, indium nitride or the mixed crystal thereof,
wherein said group 13 nitride layer comprises an upper surface and a bottom surface, and
wherein a full width at half maximum of a (1000) plane reflection of an X-ray rocking curve on said upper surface is 20000 seconds or more and 1500 seconds or less.

2. The group 13 nitride layer of claim 1,
wherein said monocrystalline particles exposed to said upper surface of said group 13 nitride layer is communicated with said bottom surface of said group 13 nitride layer without intervening a particle boundary, and
wherein a ratio DT/DB of an average cross-sectional diameter DT at outermost surfaces of said monocrystalline particles exposed to said upper surface of said group 13 nitride layer with respect to an average cross-sectional diameter DB at outermost surfaces of said monocrystalline particles exposed to said bottom surface of said group 13 nitride layer exceeds 1.0.

3. The group 13 nitride layer of claim 2, wherein said average cross-sectional diameter DT at said outermost surfaces of said monocrystalline particles exposed to said upper surface is 10 μm or larger.

4. The group 13 nitride layer of claim 1,
wherein crystal orientations of said monocrystalline particles measured through an inverse pole figure mapping of an electron back scatter diffraction (EBSD) on said upper surface are inclined with respect to said particular crystal orientation, and
wherein an average inclination angle of said crystal orientations with respect to said particular crystal orientation is 0 degree or higher and 5 degrees or lower.

5. The group 13 nitride layer of claim 1, wherein said group 13 nitride comprises a gallium nitride-based material.

6. A free-standing substrate comprising the group 13 nitride layer of claim 1.

7. A functional device comprising:
the free-standing substrate of claim 6; and
a functional layer provided on said group 13 nitride layer.

8. The functional device of claim 7, wherein said functional layer has a function of light-emitting function, rectifying function or electric power-controlling function.

9. A composite substrate comprising:
a supporting substrate; and
the group 13 nitride layer of claim 1 provided on said supporting substrate.

10. A functional device comprising:
the composite substrate of claim 9; and
a functional layer provided on said group 13 nitride layer.

11. The functional device of claim 10, wherein said functional layer has a function of light-emitting function, rectifying function or electric power-controlling function.

12. A method of producing a group 13 nitride layer, said method comprising the steps of:
film-forming an underlying layer comprising gallium oxide layer or alumina layer on a single crystal substrate;
forming a seed crystal film comprising a group 13 nitride on said underlying layer; and
providing a group 13 nitride layer comprising a polycrystalline group 13 nitride selected from gallium nitride, aluminum nitride, indium nitride or the mixed crystal thereof on said seed crystal layer, said group 13 nitride layer comprising a plurality of monocrystalline particles having a particular crystal orientation approximately in a normal direction.

13. The method of claim 12, wherein said underlying layer is formed by sputtering.

14. The method of claim 12, wherein said group 13 nitride layer is film-formed by sodium flux method.

15. The method of claim 12, further comprising the step of providing a mask for selective growth on said seed crystal layer after said seed crystal layer is formed, followed by formation of said group 13 nitride layer.
